(19) United States
(12) Patent Application Publication
(10) Pub. No.: US 2017/0101819 A1
(43) Pub. Date: Apr. 13, 2017

(54) OPTICAL SWITCHING DEVICE, METHOD OF MANUFACTURING THE SAME, AND BUILDING MATERIAL

(71) Applicant: PANASONIC INTELLECTUAL PROPERTY MANAGEMENT CO., LTD., Osaka (JP)

(72) Inventors: Yuko SUZUKA, Osaka (JP); Norihiro ITO, Osaka (JP)

(73) Assignee: PANASONIC INTELLECTUAL PROPERTY MANAGEMENT CO., LTD., Osaka (JP)

(21) Appl. No.: 15/317,260

(22) PCT Filed: Jun. 24, 2015
(86) PCT No.: PCT/JP2015/003152

§ 371 Date: Dec. 8, 2016

(30) Foreign Application Priority Data
Jul. 11, 2014 (JP) 2014-142798

(51) Int. Cl. E06B 9/24; H01L 51/50; G02F 1/1345; G02F 1/1343; G02F 1/1334; G02F 1/1335

(52) U.S. Cl. CPC E06B 9/24; G02F 1/1334; G02F 1/133509; G02F 1/1345; G02F 1/1343; H01L 51/5012; E06B 2009/2464; E06B 2009/2417

(57) ABSTRACT

An optical switching device includes: a plurality of optically variable bodies that are each variable in a degree of an optical state according to electric power; and an optical adjustment layer located between the plurality of optically variable bodies. The optically variable bodies each include: a pair of substrates; a pair of electrodes located between the pair of substrates; and an optically variable layer located between the pair of electrodes. The optical adjustment layer adheres the plurality of optically variable bodies in sheet form in a thickness direction, and adjusts a refractive index between respective substrates of adjacent optically variable bodies. The pair of electrodes have an exposed surface for supplying the electric power. An adhesion strength of the optical adjustment layer to the substrates is higher than an adhesion strength of the optically variable layer to the electrodes.

### TECHNICAL FIELD

An optical switching device, a method of manufacturing the same, and a building material are disclosed. In particular, an optical switching device capable of changing the degree of optical transparency according to electric power, a method of manufacturing the same, and a building material are disclosed.

### BACKGROUND ART

Members that change in optical transparency according to electricity are gaining attention in recent years. Members that change in optical transparency can be used in building materials such as windows. For example, a transparent organic EL element has optical transparency that changes between the light emitting state and the non-light emitting state. An organic EL element that changes in optical property is, for example, described in Patent Literature (PTL) 1. In PTL 1, an optical layer for changing the traveling direction of light is provided to change the optical property of the organic EL element.

### CITATION LIST

### Patent Literature

PTL 1: Japanese Unexamined Patent Application Publication No. 2013-201009

### SUMMARY OF THE INVENTION

### Technical Problem

A member that changes in optical transparency is expected to have improved optical property by providing variations in the change between the transparent state and the non-transparent state. In the case where the member has a plurality of optical transparency changing parts, the structure is complex, and therefore it is important to stably manufacture the member so that these parts function optically favorably.

The present disclosure has an object of providing an optical switching device that is stably manufactured and has excellent optical property, a method of manufacturing the same, and a building material.

### Solutions to Problem

An optical switching device according to an aspect of the present disclosure includes: a plurality of optically variable bodies that are sheetlike and are each variable in a degree of an optical state according to electric power; and an optical adjustment layer located between the plurality of optically variable bodies, wherein the optically variable bodies include: a pair of substrates; a pair of electrodes located between the pair of substrates; and an optically variable layer located between the pair of electrodes and variable in the degree of the optical state, the optical adjustment layer adheres the plurality of optically variable bodies in sheet form in a thickness direction, and adjusts a refractive index between respective substrates of adjacent optically variable bodies in a visible light wavelength range, the pair of electrodes have an exposed surface for supplying the electric power, and an adhesion strength of the optical adjustment layer to the substrates is higher than an adhesion strength of the optically variable layer to the electrodes.

A building material according to an aspect of the present disclosure includes: the optical switching device; and wiring.

A method of manufacturing the optical switching device according to an aspect of the present disclosure includes: adhering the plurality of optically variable bodies by the optical adjustment layer; making, in a side end portion of the plurality of optically variable bodies, a cut from a substrate located at one end in the thickness direction to an optically variable layer located at an other end in the thickness direction; and removing the side end portion of the plurality of optically variable bodies along the cut to expose an electrode.

### Advantageous Effects of Invention

The optical switching device according to the present disclosure is stably manufactured and has excellent optical property. The building material according to the present disclosure has excellent optical property. The method of manufacturing an optical switching device according to the present disclosure can easily manufacture an optical switching device having excellent optical property.

### BRIEF DESCRIPTION OF DRAWINGS

FIG. 1 is a schematic sectional diagram illustrating an example of an optical switching device.

FIG. 2 is a schematic sectional diagram illustrating an example of an optical switching device.

FIG. 3 is a schematic sectional diagram illustrating an example of an optical switching device.

FIG. 4 is a schematic sectional diagram illustrating an example of a method of manufacturing an optical switching device, where A illustrates a plurality of optically variable bodies before adhesion, B illustrates the state after adhering the plurality of optically variable bodies, C illustrates the state after making cuts, D illustrates the state after removing side end portions, and E illustrates the state after wiring.

FIG. 5 is a schematic diagram illustrating the functioning states of a plurality of optically variable units in the optical switching device, where A illustrates the state where light scattering is performed, B illustrates the state where light is emitted, C illustrates the state where light reflection is performed, D illustrates the state where light absorption is performed, E illustrates the state where light scattering is performed and light is emitted, F illustrates the state where light scattering and light reflection are performed, G illustrates the state where light scattering and light absorption are performed, H illustrates the state where light reflection is performed and light is emitted, I illustrates the state where light absorption is performed and light is emitted, J illustrates the state where light reflection and light absorption are performed, K illustrates the state where light scattering and light reflection are performed and light is emitted, L illustrates the state where light scattering and light absorption are performed and light is emitted, M illustrates the state where light scattering, light reflection, and light absorption are performed, N illustrates the state where light reflection and light absorption are performed and light is emitted, P illustrates the state where light scattering, light reflection, and light absorption are performed and light is emitted, and Q illustrates the state where light scattering, light reflection, and light absorption are all not performed and light is not emitted.

FIG. 6 is a schematic diagram illustrating an example of a building material including the optical switching device.

### DESCRIPTION OF EXEMPLARY EMBODIMENT

### Embodiment

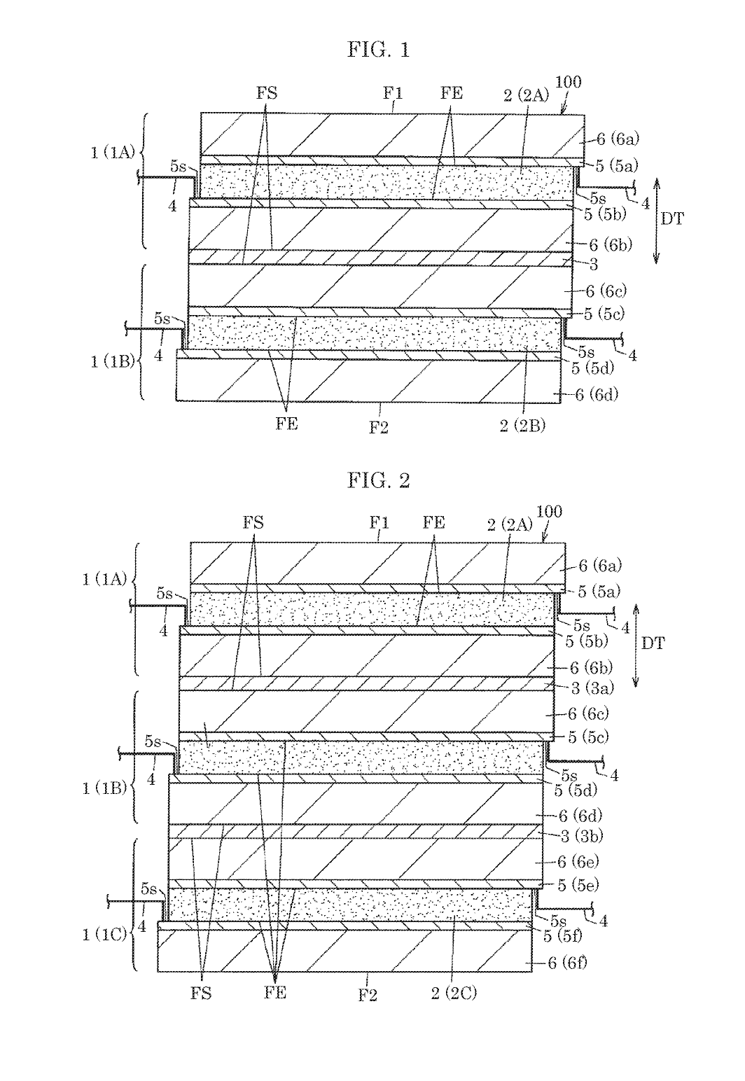

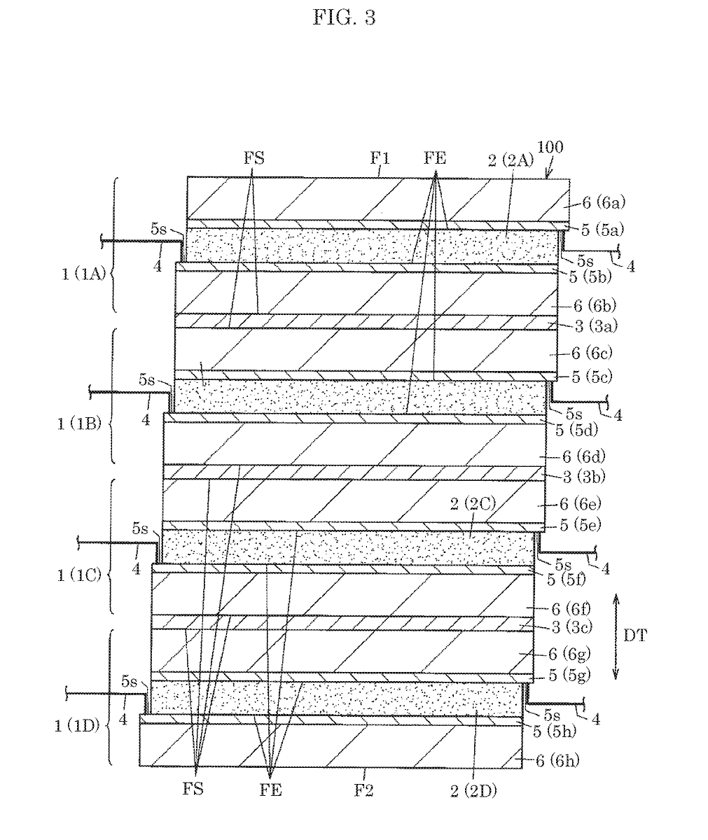

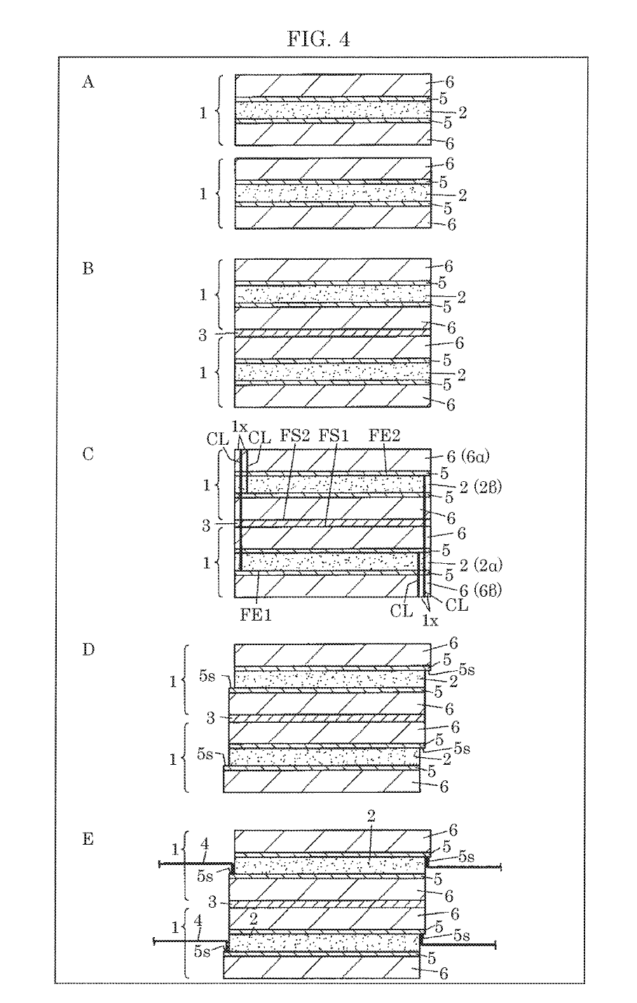

An optical switching device is disclosed below. FIG. 1 illustrates an example of optical switching device 100. FIG. 2 illustrates another example of optical switching device 100. FIG. 3 illustrates still another example of optical switching device 100.

Optical switching device 100 includes plurality of optically variable bodies 1. In the example in FIG. 1, plurality of optically variable bodies 1 are first optically variable body 1A and second optically variable body 1B. In the example in FIG. 2, plurality of optically variable bodies 1 are first optically variable body 1A, second optically variable body 1B, and third optically variable body 1C. In the example in FIG. 3, plurality of optically variable bodies 1 are first optically variable body 1A, second optically variable body 1B, third optically variable body 1C, and fourth optically variable body 1D. The inclusion of plurality of optically variable bodies 1 improves the optical property.

Optically variable body 1 is sheetlike. Optically variable body 1 is variable in the degree of the optical state according to electric power. The optical state mentioned here means any of the states of transparency, light emission, light scattering, light reflection, and light absorption. Optically variable body 1 includes pair of substrates 6, pair of electrodes 5, and optically variable layer 2. Pair of electrodes 5 are located between pair of substrates 6. Optically variable layer 2 is located between pair of electrodes 5. Optically variable layer 2 is variable in the degree of the optical state. Electrode 5 has exposed surface 5s for supplying electric power in planar view. Exposed surface 5s eases the supply of electric power.

Optical switching device 100 includes optical adjustment layer 3. Optical adjustment layer 3 is located between plurality of optically variable bodies 1. Optical adjustment layer 3 adheres plurality of optically variable bodies 1 in sheet form in the thickness direction. Optical adjustment layer 3 adjusts the refractive index between substrates 6 of adjacent optically variable bodies 1 in a visible light wavelength range. The adhesion strength of optical adjustment layer 3 to substrates 6 is higher than the adhesion strength of optically variable layer 2 to electrodes 5. The optical property is improved by optical adjustment layer 3 adjusting the difference in refractive index between the substrates. Moreover, the adhesion between adjacent substrates 6 is enhanced as optical adjustment layer 3 has adhesiveness

The thickness direction is the direction of the thickness of optical switching device 100. In FIGS. 1 to 3, the thickness direction is designated by arrow DT. The thickness direction may be the direction perpendicular to the surface of substrate 6. In FIGS. 1 to 3, each layer of optical switching device 100 can be regarded as extending in the direction perpendicular to the thickness direction. The term “planar view” means a view along the direction (thickness direction DT) perpendicular to the surface of substrate 6.

Optical switching device 100 is sheetlike. Optical switching device 100 may be panel-shaped. Optical switching device 100 switches the state of light.

Optical switching device 100 has first surface F1 and second surface F2 opposite to first surface F1. First surface F1 and second surface F2 are outer surfaces. These surfaces may be exposed. Alternatively, first surface F1 and second surface F2 may each be covered with another transparent sheetlike member.

The surfaces of optical switching device 100 include flat and curved surfaces. The surfaces may all be flat surfaces. Alternatively, the surfaces may all be curved surfaces. For example, the surfaces may be arc-like. Alternatively, the surfaces may include both flat and curved surfaces.

FIGS. 1 to 3 each illustrate an example of optical switching device 100, and the optical switching device is not limited to such. FIGS. 1 to 3 and the other drawings schematically illustrate optical switching device 100 and each component in optical switching device 100, which may be different from the actual dimensional relationships and the like. In the drawings, components given the same reference sign are the same components, and the description on any of such components is commonly applicable, unless otherwise stated.

Pair of electrodes 5 and optically variable layer 2 located between pair of electrodes 5 constitute an optically variable unit. The optically variable unit is a main part in optically variable body 1. The optically variable unit may be optically variable body 1 except substrates 6. Optical switching device 100 has a plurality of optically variable units.

The plurality of optically variable units are supported by plurality of substrates 6. Each optically variable unit is located between one pair of substrates 6. The optically variable unit is thus protected. The optically variable unit, by being supported by substrates 6, can be manufactured easily and stabilized.

In FIGS. 1 to 3, plurality of substrates 6 are designated as substrates 6a, 6b, 6c, 6d, 6e, 6f, 6g, and 6h in order from the first surface F1 side, for the sake of convenience.

Optical switching device 100 may have plurality of substrates 6. Plurality of substrates 6 have optical transparency. Such optical switching device 100 has high optical property. Substrates 6 can function as substrates for supporting the layers of optical switching device 100. Substrates 6 can function as substrates for sealing the layers of optical switching device 100. Plurality of substrates 6 are arranged in the thickness direction.

Optical switching device 100 may have the plurality of optically variable units between two substrates 6 located outside from among plurality of substrates 6. The plurality of optically variable units can thus be protected by substrates 6.

Substrate 6 may be a glass substrate, a resin substrate, or the like. In the case where substrate 6 is a glass substrate, optical switching device 100 has excellent optical property as glass has high transparency. In addition, since glass has low moisture permeability, moisture can be kept from entering the sealed region. Further, since glass may have ultraviolet absorptivity, device degradation can be prevented. Examples of glass include soda glass, alkali-free glass, and high refractive index glass. Thin-film glass may be used as substrate 6. In this case, optical switching device 100 not only has high transparency and high dampproofness but also is flexible. In the case where substrate 6 is a resin substrate, optical switching device 100 is safe as it is prevented from scattering upon breaking because a resin resists fracture. In addition, the use of a resin substrate can make optical switching device 100 flexible. The resin substrate may be filmlike. Examples of the resin include polyethylene terephthalate (PET) and polyethylene naphthalate (PEN).

Two substrates 6 located outside from among plurality of substrates 6 may be glass substrates. Such optical switching device 100 has excellent optical property. Plurality of substrates 6 may all be glass substrates. In this case, the optical condition can be controlled easily to enhance the optical property. Any one or more of inner substrates 6 may be resin substrates. Such optical switching device 100 is safe, as it is prevented from scattering upon breaking. The surface of substrate 6 may be coated with any one or more of an antifouling material, an ultraviolet screening material, an ultraviolet absorbing material, and a dampproof material. This enhances protection.

Electrode 5 may be a transparent conductive layer. The material of the transparent conductive layer may be a transparent metal oxide, a conductive particle-containing resin, a metal thin film, or the like. Electrode 5 may be made of a conductive material suitable for each location. The material of electrode 5 having optical transparency is, for example, a transparent metal oxide such as ITO or IZO. Electrode 5 made of a transparent metal oxide is suitably used as electrode 5 in optically variable body 1. Electrode 5 may be a layer containing silver nanowires or a transparent metal layer of thin-film silver or the like. Electrode 5 may be formed by stacking a transparent metal oxide layer and a metal layer. Electrode 5 may be a transparent conductive layer provided with wiring for electrical assistance. Electrode 5 may have a thermal insulation effect. This can improve thermal insulation performance. A dampproof layer may be formed between substrate 6 and electrode 5. The dampproof layer keeps moisture from entering into optical switching device 100, thus suppressing the degradation of optical switching device 100.

Pair of electrodes 5 are two electrodes 5 electrically paired with each other. One of pair of electrodes 5 forms an anode, and the other one of pair of electrodes 5 forms a cathode. One of pair of electrodes 5 may be located on the first surface F1 side, and the other one of pair of electrodes 5 on the second surface F2 side. Pair of electrodes 5 may be located only on the first surface F1 side or on the second surface F2 side.

Plurality of electrodes 5 may be electrically connectable to a power source. Optical switching device 100 may have electrode pads, an electrical connection electrically combining the electrode pads, etc., for connection to the power source. The electrical connection may be a plug or the like.

Electrode 5 has exposed surface 5s. Exposed surface 5s is a surface for supplying electric power to electrode 5. Exposed surface 5s of electrode 5 is situated in a side end portion of optical switching device 100. Exposed surface 5s is a part of electrode 5 not in contact with optically variable layer 2. Exposed surface 5s is exposed from optically variable layer 2. Exposed surface 5s may not be exposed to the outside. Exposed surface 5s is formed by electrode 5 extending off the edge of optically variable layer 2 in planar view. Exposed surface 5s may be covered by connection wiring 4. Connection wiring 4 for electrically connecting to the power source is connected to exposed surface 5s. Optical switching device 100 may include connection wiring 4. Exposed surface 5s of electrode 5 eases the electrical connection to the power source, so that electric power can be favorably supplied to the plurality of optically variable units. Connection wiring 4 further eases the electrical connection.

In FIGS. 1 to 3, plurality of electrodes 5 are designated as electrodes 5a, 5b, 5c, 5d, 5e, 5f, 5g, and 5h in order from the first surface F1 side, for the sake of convenience.

Each optically variable unit includes optically variable layer 2. Optically variable layer 2 is located between pair of electrodes 5. Optically variable layer 2 is supplied with electric power via pair of electrodes 5, and varies in the degree of the optical state. Pair of electrodes 5 function as electrodes for driving optically variable layer 2. Optically variable layer 2 in first optically variable body 1A is defined as first optically variable layer 2A. Likewise, respective optically variable layers 2 in second optically variable body 1B to fourth optically variable body 1D are defined as second optically variable layer 2B, third optically variable layer 2C, and fourth optically variable layer 2D.

The plurality of optically variable units are each selected from a sheetlike light emitting unit, a light scattering variable unit, a light reflection variable unit, and a light absorption variable unit. The sheetlike light emitting unit may be an element that emits light in sheet form according to supplied electric power. The light scattering variable unit may be an element variable in the degree of light scattering according to electric power. The light reflection variable unit may be an element variable in the degree of light reflection according to electric power. The light absorption variable unit may be an element variable in the degree of light absorption according to electric power.

Optically variable body 1 having the sheetlike light emitting unit is defined as a sheetlike light emitting body. Optically variable body 1 having the light scattering variable unit is defined as a light scattering variable body. Optically variable body 1 having the light reflection variable unit is defined as a light reflection variable body. Optically variable body 1 having the light absorption variable unit is defined as a light absorption variable body. Optical switching device 100 may include two or more optically variable bodies 1 each selected from the sheetlike light emitting body, the light scattering variable body, the light reflection variable body, and the light absorption variable body.

The plurality of optically variable units may include the sheetlike light emitting unit. The sheetlike light emitting unit is capable of emitting light in sheet form. The sheetlike light emitting unit may be an organic electroluminescent element (organic EL element). Thin and large-area light emission can be obtained in this way. The sheetlike light emitting unit may be transparent.

In the case where the optically variable unit is an organic EL element, optically variable layer 2 may be an organic light emitting layer. The organic EL element is an element having the structure in which the organic light emitting layer is located between pair of electrodes 5. When the sheetlike light emitting unit is the organic EL element, a thin and transparent light emitter with excellent optical property can be realized. In this case, the optical switching device is capable of surface light emission. The organic light emitting layer has optical transparency. Hence, during light emission, light from the organic light emitting layer can be emitted to both sides in the thickness direction. During non-light emission, light can be transmitted from one side to the other side.

The organic light emitting layer is a layer having a function of emitting light, and may be composed of a plurality of functional layers selected as appropriate from a hole injection layer, a hole transport layer, a light emitting material-containing layer, an electron transport layer, an electron injection layer, an intermediate layer, and the like. The organic light emitting layer may be a single layer of the light emitting material-containing layer. In the organic EL element, holes and electrons are combined in the light emitting material-containing layer to emit light by causing the flow of electricity between pair of electrodes 5.

The current direction in the organic EL element is typically one way. Accordingly, a DC power source may be connected. DC may be converted from AC. The use of a DC power source enables stable light emission. The light emitting color of the organic EL element may be white, and may be blue, green, or red. The light emitting color may be an intermediate color between blue and green or between green and red. Toning may be performed according to applied current.

The plurality of optically variable units may include the light scattering variable unit. The light scattering variable unit is variable in the degree of light scattering. The variability in the degree of light scattering may be the capability of adjusting between a high scattering state and a low scattering state. Alternatively, the variability in the degree of light scattering may be the capability of adjusting between a state with light scattering and a state without light scattering. When the degree of light scattering is adjustable, the optical state can be changed. Such optical switching device 100 has excellent optical property. The light scattering variable unit may be layered.

The high scattering state is a state with high light scattering. The high scattering state is, for example, a state where light which has entered from one surface has its traveling direction changed to various directions by scattering and dispersedly exits from the other surface. The high scattering state may be a state where, when viewing an object present on the other surface side from one surface side, the object appears blurred. The high scattering state may be a translucent state. In the case where the light scattering variable unit performs light scattering, the light scattering variable unit functions as a scattering layer that scatters light.

The low scattering state is a state with low light scattering or no light scattering. The low scattering state is, for example, a state where light which has entered from one surface exits from the other surface while maintaining its traveling direction. The low scattering state may be a state where, when viewing an object present on the other surface side from one surface side, the object is clearly visible. The low scattering state may be a transparent state.

The light scattering variable unit may have the high scattering state with high light scattering, the low scattering state with low light scattering or no light scattering, and a state of performing light scattering between the high scattering state and the low scattering state. When the light scattering variable unit can perform light scattering between the high scattering state and the low scattering state, intermediate light scattering is realized. This enables the optical state to be changed with wide variation, and further improves the optical property. The state of performing light scattering between the high scattering state and the low scattering state is hereafter referred to as an intermediate scattering state.

The intermediate scattering state may have at least one scattering state between the high scattering state and the low scattering state. For example, the optical property is improved if light scattering can be changed by switching between the three states of the high scattering state, the intermediate scattering state, and the low scattering state. The intermediate scattering state may have a plurality of states that differ in the degree of scattering, between the high scattering state and the low scattering state. By setting a plurality of levels in the degree of scattering in this way, the optical property can be further enhanced. For example, the optical property is improved if light scattering can be changed in a plurality of levels by switching between the plurality of states of the high scattering state, the plurality of intermediate scattering states, and the low scattering state. The intermediate scattering state may be a state that changes continuously from the high scattering state to the low scattering state. In such a case, the degree of scattering changes continuously. This enables the optical state to be changed with wide variation, and further improves the optical property. For example, the optical property is improved if light scattering can be changed in a state of performing desired light scattering between the high scattering state and the low scattering state to thus create an intermediate state. In the case where the light scattering variable unit has the intermediate scattering state, the light scattering variable unit may be capable of maintaining the intermediate scattering state.

The light scattering variable unit may scatter at least part of visible light. The light scattering variable unit may scatter the whole visible light. The light scattering variable unit may scatter infrared light or ultraviolet light.

In the case where the optically variable unit is the light scattering variable unit, optically variable layer 2 may be a light scattering variable layer. The light scattering variable layer is located between pair of electrodes 5. The degree of light scattering in the light scattering variable layer is changed by applying a voltage between pair of electrodes 5.

The light scattering variable unit may be connected to an AC power source. Many materials that vary in light scattering according to an electric field are, once time has passed from the start of voltage application, unable to maintain the light scattering state at the time of voltage application. With the AC power source, voltage can be applied alternately in both directions, and continuous voltage application can be substantially performed by changing the voltage direction. Thus, stable light scattering can be achieved by using the AC power source. The AC waveform may be rectangular. This eases the application of constant voltage, and so contributes to more stable light scattering. AC power may be pulses. The intermediate scattering state may be created by controlling the amount of voltage application.

The material of the light scattering variable layer may be a material whose molecular orientation varies according to electric field modulation. For example, the material is a liquid crystal material. The material of the light scattering variable layer may be a polymer dispersed liquid crystal (PDLC). In the PDLC, a liquid crystal is held by a polymer, so that a stable light scattering variable layer can be formed. As the material of the light scattering variable layer, a solid substance that varies in scattering according to an electric field may also be used.

The PDLC may be composed of a resin portion and a liquid crystal portion. The resin portion is formed by a polymer. The resin portion may have optical transparency. This enables the light scattering variable unit to have optical transparency. The resin portion may be made of a thermosetting resin, an ultraviolet curable resin, or the like. The liquid crystal portion is a portion whose liquid crystal structure varies according to an electric field. For example, the liquid crystal portion is a nematic liquid crystal. The PDLC may have a structure in which the liquid crystal portions are scattered in the resin portion. Such PDLC may have a sea-island structure where the resin portion is the sea and the liquid crystal portions are the islands. The PDLC may have a shape in which the liquid crystal portions are irregularly connected like a net in the resin portion. Alternatively, the PDLC may have a structure in which the resin portions are scattered in the liquid crystal portion or the resin portions are irregularly connected like a net in the liquid crystal portion.

The light scattering variable unit may be in the light scattering state when no voltage is applied, and in the light transmission state when a voltage is applied. Such control may be performed with the PDLC. This is because a liquid crystal can be aligned by voltage application. With the PDLC, a thin light scattering variable unit with high light scattering property can be formed. The light scattering variable unit may be in the light transmission state when no voltage is applied, and in the light scattering state when a voltage is applied.

The light scattering variable layer may maintain the light scattering state at the time of voltage application. This enhances power efficiency. The property of maintaining the light scattering state is called hysteresis. The time for maintaining the light scattering state may be long, e.g. one hour or more.

The plurality of optically variable units may include the light reflection variable unit. The light reflection variable unit is variable in the degree of light reflection. The variability in the degree of light reflection may be the capability of adjusting between a high reflection state and a low reflection state. Alternatively, the variability in the degree of light reflection may be the capability of adjusting between a state with light reflection and a state without light reflection. When the degree of light reflection is adjustable, the optical state can be changed. Such optical switching device 100 has excellent optical property. The light reflection variable unit may be layered.

The high reflection state is a state with high light reflection. The high reflection state is, for example, a state where light which has entered from one surface has its traveling direction changed to the opposite direction by reflection and exits from the surface of incidence. The high reflection state may be a state where an object present on the other surface side is not visible from one surface side. The high reflection state may be a state where, when viewing the light reflection variable unit from one surface side, an object present on the same surface side is visible. The high reflection state may be a mirror state. In the case where the light reflection variable unit performs light reflection, the light reflection variable unit functions as a reflection layer that reflects light.

The low reflection state is a state with low light reflection or no light reflection. The low reflection state is, for example, a state where light which has entered from one surface exits from the other surface while maintaining its traveling direction. The low reflection state may be a state where, when viewing an object present on the other surface side from one surface side, the object is clearly visible. The low reflection state may be a transparent state.

The light reflection variable unit may have the high reflection state with high light reflection, the low reflection state with low light reflection or no light reflection, and a state of performing light reflection between the high reflection state and the low reflection state. When the light reflection variable unit can perform light reflection between the high reflection state and the low reflection state, intermediate light reflection is realized. This enables the optical state to be changed with wide variation, and further improves the optical property. The state of performing light reflection between the high reflection state and the low reflection state is hereafter referred to as an intermediate reflection state.

The intermediate reflection state may have at least one reflection state between the high reflection state and the low reflection state. For example, the optical property is improved if light reflection can be changed by switching between the three states of the high reflection state, the intermediate reflection state, and the low reflection state. The intermediate reflection state may have a plurality of states that differ in the degree of reflection, between the high reflection state and the low reflection state. By setting a plurality of levels in the degree of reflection in this way, the optical property can be further enhanced. For example, the optical property is improved if light reflection can be changed in a plurality of levels by switching between the plurality of states of the high reflection state, the plurality of intermediate reflection states, and the low reflection state. The intermediate reflection state may be a state that changes continuously from the high reflection state to the low reflection state. In such a case, the degree of reflection changes continuously. This enables the optical state to be changed with wide variation, and further improves the optical property. For example, the optical property is improved if light reflection can be changed in a state of performing desired light reflection between the high reflection state and the low reflection state to thus create an intermediate state. In the case where the light reflection variable unit has the intermediate reflection state, the light reflection variable unit may be capable of maintaining the intermediate reflection state.

The light reflection variable unit may reflect at least part of visible light. The light reflection variable unit may reflect the whole visible light. The light reflection variable unit may reflect infrared light. The light reflection variable unit may reflect ultraviolet light. In the case where the light reflection variable unit reflects all of visible light, ultraviolet light, and infrared light, the optical switching device 100 is stable and has excellent optical property.

The light reflection variable unit may be capable of changing the shape of reflection spectrum. The reflection spectrum may be changed in the intermediate reflection state. Changing the shape of reflection spectrum means that light entering the light reflection variable unit and light reflected in the light reflection variable unit have different spectrum shapes. The reflection spectrum is changed by changing the reflection wavelength. For example, the shape of reflection spectrum is changed by strongly reflecting only blue light, strongly reflecting only green light, or strongly reflecting only red light. When the reflection spectrum changes, the color of light changes. This enables toning (color adjustment), and improves the optical property.

The light reflection variable unit may be capable of reflecting light without changing the shape of reflection spectrum. In such a case, since there is no spectrum change between incident light and reflected light, the degree of reflection can be easily increased or decreased. The capability of controlling the degree of reflection enables toning (color adjustment), and improves the optical property.

In the case where the optically variable unit is the light reflection variable unit, optically variable layer 2 may be a light reflection variable layer. The light reflection variable layer is located between pair of electrodes 5. The degree of light reflection in the light reflection variable layer is changed by applying a voltage between pair of electrodes 5.

The light reflection variable unit may be connected to an AC power source. Many materials that vary in light reflection according to an electric field are, once time has passed from the start of voltage application, unable to maintain the light reflection state at the time of voltage application. With the AC power source, voltage can be applied alternately in both directions, and continuous voltage application can be substantially performed by changing the voltage direction. Thus, stable light reflection can be achieved by using the AC power source. The AC waveform may be rectangular. This eases the application of constant voltage, and so contributes to more stable light reflection. AC power may be pulses. The intermediate reflection state may be created by controlling the amount of voltage application.

The material of the light reflection variable layer may be a material whose molecular orientation varies according to electric field modulation. Examples include a nematic liquid crystal, a cholesteric liquid crystal (CLC), a ferroelectric liquid crystal, and an electrochromic material. The CLC may be a nematic liquid crystal having a helical structure. The CLC may be a chiral nematic liquid crystal. In the CLC, the orientation direction of the molecular axis changes continuously in the space, creating a macroscopic helical structure. Light reflection corresponding to the helical period is therefore possible. Control between light reflection and light transmission can be performed by changing the liquid crystal state according to an electric field. In the electrochromic material, the color change phenomenon of the substance by electrochemical reversible reaction (electrolytic oxidation-reduction reaction) according to voltage application can be utilized to enable control between light reflection and light transmission. The material of the light reflection variable layer may be the CLC or the electrochromic material.

The light reflection variable unit may be in the light reflection state when no voltage is applied, and in the light transmission state when a voltage is applied. Such control may be performed with the CLC or the electrochromic material. This is because a liquid crystal can be aligned by voltage application. With the CLC or the electrochromic material, a thin light reflection variable unit with high light reflection property can be formed. The state of reflecting only specific light without voltage application may be referred to as planar orientation, and the state of allowing light to pass with voltage application as focal-conic orientation. The light reflection variable unit may be in the light transmission state when no voltage is applied, and in the light reflection state when a voltage is applied.

The light reflection variable layer may maintain the light reflection state at the time of voltage application. This enhances power efficiency. The property of maintaining the light reflection state is called hysteresis. The time for maintaining the light reflection state may be long, e.g. one hour or more.

The plurality of optically variable units may include the light absorption variable unit. The light absorption variable unit is variable in the degree of light absorption. The variability in the degree of light absorption may be the capability of adjusting between a high absorption state and a low absorption state. Alternatively, the variability in the degree of light absorption may be the capability of adjusting between a state with light absorption and a state without light absorption. When the degree of light absorption is adjustable, the optical state can be changed. Such optical switching device 100 has excellent optical property. The light absorption variable unit may be layered.

The high absorption state is a state with high light absorption. The high absorption state is, for example, a state where light which has entered from one surface does not exit from the other surface by absorption. The high absorption state may be a state where an object present on the other surface side is not visible from one surface side. The high absorption state may be a state where an object present on the other surface side is not visible from each surface side. The high absorption state may be an opaque state. In the high absorption state, the light absorption variable unit may be black in color. In the case where the light absorption variable unit performs light absorption, the light absorption variable unit functions as an absorption layer that absorbs light.

The low absorption state is a state with low light absorption or no light absorption. The low absorption state is, for example, a state where light which has entered from one surface is not absorbed and exits from the other surface while maintaining its traveling direction. The low absorption state may be a state where, when viewing an object present on the other surface side from one surface side, the object is clearly visible. The low absorption state may be a transparent state.

The light absorption variable unit may have the high absorption state with high light absorption, the low absorption state with low light absorption or no light absorption, and a state of performing light absorption between the high absorption state and the low absorption state. When the light absorption variable unit can perform light absorption between the high absorption state and the low absorption state, intermediate light absorption is realized. This enables the optical state to be changed with wide variation, and further improves the optical property. The state of performing light absorption between the high absorption state and the low absorption state is hereafter referred to as an intermediate absorption state.

The intermediate absorption state may have at least one absorption state between the high absorption state and the low absorption state. For example, the optical property is improved if light absorption can be changed by switching between the three states of the high absorption state, the intermediate absorption state, and the low absorption state. The intermediate absorption state may have a plurality of states that differ in the degree of absorption, between the high absorption state and the low absorption state. By setting a plurality of levels in the degree of absorption in this way, the optical property can be further enhanced. For example, the optical property is improved if light absorption can be changed in a plurality of levels by switching between the plurality of states of the high absorption state, the plurality of intermediate absorption states, and the low absorption state. The intermediate absorption state may be a state that changes continuously from the high absorption state to the low absorption state. In such a case, the degree of absorption changes continuously. This enables the optical state to be changed with wide variation, and further improves the optical property. For example, the optical property is improved if light absorption can be changed in a state of performing desired light absorption between the high absorption state and the low absorption state to thus create an intermediate state. In the case where the light absorption variable unit has the intermediate absorption state, the light absorption variable unit may be capable of maintaining the intermediate absorption state.

The light absorption variable unit may absorb at least part of visible light. This produces sharp light emission. The light absorption variable unit may absorb the whole visible light. This produces sharper light emission. The light absorption variable unit may absorb infrared light. Absorbing infrared light has a heat shielding effect. The light absorption variable unit may absorb ultraviolet light. This prevents the degradation of optical switching device 100. Moreover, by absorbing ultraviolet light, ultraviolet light can be kept from entering indoors. The light absorption variable unit may absorb any one of visible light, ultraviolet light, and infrared light, may absorb any two of visible light, ultraviolet light, and infrared light, and may absorb all of visible light, ultraviolet light, and infrared light.

The light absorption variable unit may be capable of changing the shape of absorption spectrum. The absorption spectrum may be changed in the intermediate absorption state. Changing the shape of absorption spectrum means that light entering the light absorption variable unit and light having passed through the light absorption variable unit have different spectrum shapes. The absorption spectrum is changed by changing the absorption wavelength. For example, the spectrum shape is changed by strongly absorbing only blue light, strongly absorbing only green light, or strongly absorbing only red light. When the absorption spectrum changes, the color of light passing through optical switching device 100 changes. This enables toning (color adjustment) for transmitted light, and improves the optical property.

In the case where the optically variable unit is the light absorption variable unit, optically variable layer 2 may be a light absorption variable layer. The light absorption variable layer is located between pair of electrodes 5. The degree of light absorption in the light absorption variable layer is changed by applying a voltage between pair of electrodes 5.

The light absorption variable unit may be connected to a DC power source or an AC power source. For example, the light absorption variable unit is connected to a DC power source. In a material whose light absorption varies according to an electric field, light absorption can be changed by the flow of electricity in one direction. Thus, stable light absorption can be achieved by using the DC power source. The intermediate absorption state may be created by controlling the amount of voltage or current application.

The material of the light absorption variable layer may be a material whose light absorption varies according to electric field modulation. The material for electric field modulation is, for example, tungsten oxide.

The light absorption variable unit may be in the light transmission state when no voltage is applied, and in the light absorption state when a voltage is applied. A liquid crystal material can change in absorption according to voltage application. A liquid crystal can be aligned according to voltage application. With the liquid crystal, a thin light absorption variable unit with high absorption property can be formed. The light absorption variable unit may be in the light absorption state when no voltage is applied, and in the light transmission state when a voltage is applied.

The light absorption variable layer may maintain the light absorption state at the time of voltage application. This enhances power efficiency. The property of maintaining the light absorption state is called hysteresis. The time for maintaining the light absorption state may be long, e.g. one hour or more.

In optical switching device 100, first surface F1 is defined as a main surface, and second surface F2 as a back surface. The main surface is set in the direction in which light is to be obtained. For example, in the case where optical switching device 100 is used as a window, the main surface (first surface F1) is situated inside and the back surface (second surface F2) is situated outside.

Table 1 shows examples of the structure of the plurality of optically variable units. In Table 1, each component which optical switching device 100 has as an optically variable unit is indicated by “∘”. Table 1 also shows the functions in the case of selecting each component. The optically variable units may be arranged in any order.

TABLE 1

| | Light | Sheetlike | Light | Light | |
|---|---|---|---|---|---|
| Struc- | scattering | light | reflection | absorption | |
| tural | variable | emitting | variable | variable | |
| example | unit | unit | unit | unit | Function |
| 1 | ∘ | ∘ | | | Suppression of |
| | | | | | angular |
| | | | | | dependence of |
| | | | | | light emission |
| 2 | | ∘ | ∘ | | Improvement of |
| | | | | | light emission |
| | | | | | efficiency |
| 3 | | | ∘ | ∘ | Light shielding |
| | | | | | Usable as mirror |
| 4 | ∘ | | | ∘ | Light shielding |
| | | | | | White lightproof |
| | | | | | curtain Lace |
| | | | | | curtain |
| 5 | | ∘ | | ∘ | Improvement of |
| | | | | | contrast of light |
| | | | | | emission |
| 6 | ∘ | | ∘ | | Light shielding |
| | | | | | Improvement of |
| | | | | | thermal |
| | | | | | insulation |
| 7 | ∘ | ∘ | ∘ | | High-efficiency |
| | | | | | light emission |
| | | | | | Suppression of |
| | | | | | angular |
| | | | | | dependence of |
| | | | | | light emission |
| 8 | | ∘ | ∘ | ∘ | Light shielding |
| | | | | | High-efficiency |
| | | | | | light emission |
| | | | | | Improvement of |
| | | | | | contrast of light |
| | | | | | emission |
| 9 | ∘ | ∘ | | ∘ | Window and |
| | | | | | lighting function |
| 10 | ∘ | | ∘ | ∘ | Window function |
| | | | | | (light shielding, |
| | | | | | curtain, thermal |
| | | | | | insulation) |
| 11 | ∘ | ∘ | ∘ | ∘ | All of foregoing |
| | | | | | functions |

The light reflection variable unit may be located closer to second surface F2 than the sheetlike light emitting unit and the light scattering variable unit. In this case, light can be extracted using reflection. Such optical switching device 100 has excellent optical property.

The light absorption variable unit may be located closest to second surface F2 of the plurality of optically variable units. In this case, light entering from second surface F2 can be absorbed. Moreover, light exiting from first surface F1 has higher contrast.

The plurality of optically variable units may be arranged in the order of the light scattering variable unit, the sheetlike light emitting unit, the light reflection variable unit, and the light absorption variable unit in the direction from first surface F1 to second surface F2. In the case where the number of optically variable units is two or three, suitable arrangement is derived by removing part of the aforementioned four units.

In optical switching device 100, the plurality of optically variable units may include the organic electroluminescent element (sheetlike light emitting unit) and the light scattering variable unit. A sheetlike light emitter with excellent optical property can thus be obtained. The sheetlike light emitter may be used as a lighting device.

Although the above describes an example where the plurality of optically variable units are each a different one of any of the light scattering variable unit, the sheetlike light emitting unit, the light reflection variable unit, and the light absorption variable unit, two or more components of the same type may be selected. For example, the plurality of optically variable units may include two or more light scattering variable units. For example, the plurality of optically variable units may include two or more sheetlike light emitting units. For example, the plurality of optically variable units may include two or more light reflection variable units. For example, the plurality of optically variable units may include two or more light absorption variable units. The inclusion of two or more components of the same type of function (scattering, light emission, reflection, or absorption) enhances the function.

As illustrated in each of the examples in FIGS. 1 to 3, optical adjustment layer 3 adheres adjacent optically variable bodies 1 together. Optical adjustment layer 3 fills the space between adjacent optically variable bodies 1. Typically, in the case where two transparent substrates are stacked with a space in between, when viewing the other side from one side through the structure, the contour of an object present on the other side tends to be blurred. In detail, double reflection or multiple reflection can arise. In optical switching device 100, however, optical adjustment layer 3 is located between substrates 6, so that the difference of refractive index from substrate 6 is adjusted and the phenomenon such as double reflection or multiple reflection is suppressed. This is because optical adjustment layer 3 performs refractive index matching. The presence of optical adjustment layer 3 also suppresses interface reflection which occurs on the surface of substrate 6, as a result of which optical loss is reduced to improve light transmission efficiency. Optical adjustment layer 3 also serves as an adhesive. Optical adjustment layer 3 can therefore adhere adjacent substrates 6 firmly. Further, in the case where plurality of substrates 6 contain glass, the glass is prevented from scattering when optical switching device 100 is broken. A safe device can thus be obtained.

Let AS be the adhesion strength of optical adjustment layer 3 to substrates 6, and AE be the adhesion strength of optically variable layer 2 to electrodes 5. In optical switching device 100, the following relationship holds:

AS>AE.

Adhesion strength AS may be the bond strength between optical adjustment layer 3 and each substrate 6. Adhesion strength AS is exerted at the interface between optical adjustment layer 3 and substrate 6. The interface between optical adjustment layer 3 and substrate 6 is designated as FS in FIGS. 1 to 3.

Adhesion strength AE may be the bond strength between optically variable layer 2 and each electrode 5. Adhesion strength AE is exerted at the interface between optically variable layer 2 and electrode 5. The interface between optically variable layer 2 and electrode 5 is designated as FE in FIGS. 1 to 3.

When the adhesion strength relationship AS>AE holds, the adhesion between the substrates is enhanced. Accordingly, even if a force acts in the direction of peeling, substrates 6 resist peeling, and a firm device is thus formed. The relationship also enhances stability against heat. This is probably because substrates 6 more susceptible to expansion and contraction due to heat than optically variable layer 2 are adhered firmly. Moreover, even when optical switching device 100 is cracked, scattering is suppressed because of high adhesion strength.

The adhesion strength relationship AS>AE also facilitates device manufacturing. Optical switching device 100 can be manufactured by stacking plurality of optically variable bodies 1 and then removing part of the side end portion to expose electrode 5, as described later. Here, if the aforementioned adhesion strength relationship holds, substrates 6 are kept from peeling when removing part of the side end portion, and so the side end portion can be removed favorably. The device can thus be manufactured easily.

The adhesion strength relationship (AS>AE) can be determined by a peeling test on optical switching device 100. For example, the adhesion strength relationship is determined by attaching adhesive tape to each of first surface F1 and second surface F2, pulling them away from each other, and observing any part of peel (separation) inside optical switching device 100. When the relationship AS>AE holds, no separation occurs between adjacent substrates 6, i.e. adjacent optically variable bodies 1, while separation occurs between optically variable layer 2 and electrode 5. This is an example of the adhesion strength test, and the adhesion may be determined by any other test.

Optical adjustment layer 3 is located between adjacent substrates 6. Suppose one of adjacent substrates 6 is substrate 6X, and the other one of adjacent substrates 6 is substrate 6Y. For example, substrate 6b is substrate 6X and substrate 6c is substrate 6Y in FIGS. 1 to 3. In the case where substrates 6X and 6Y are made of the same material, substrates 6X and 6Y have substantially the same refractive index. Here, the difference of the refractive index of optical adjustment layer 3 from the refractive index of substrate 6X (substrate 6Y) may be 0.1 or less in absolute value, and may be 0.05 or less in absolute value. A smaller difference in refractive index between substrate 6 and optical adjustment layer 3 is optically more advantageous because light reflection at the interface is suppressed. The refractive index of optical adjustment layer 3 may be the same as the refractive index of substrate 6X (substrate 6Y). The refractive index mentioned here is the refractive index in the visible light wavelength range. In the present disclosure, the visible light wavelength range is defined as a region of 450 nm to 700 nm in wavelength. Light in this wavelength range is visible to the human eye, and therefore significantly affects the transparency of optical switching device 100. Hence, adjusting the refractive index in the visible light wavelength range is optically more advantageous.

In the case where substrates 6X and 6Y are made of different materials, on the other hand, substrates 6X and 6Y may differ in refractive index. For example, in the case where one of substrates 6X and 6Y is glass and the other one of substrates 6X and 6Y is a resin, their refractive indices are likely to be different. Even when substrates 6X and 6Y are both glass (or a resin), their refractive indices may be different if different materials are used. Optical adjustment layer 3 may have a refractive index between the refractive indices of substrates 6X and 6Y adhered by optical adjustment layer 3. This reduces the refractive index difference, and improves the optical property.

In the case where the refractive index of optical adjustment layer 3 is between the refractive indices of substrates 6X and 6Y, the refractive index of optical adjustment layer 3 may change gradually in the thickness direction. Such gradual change of the refractive index further reduces the refractive index difference and improves the optical property. For example, in the case where the refractive index of one substrate 6X is higher than the refractive index of the other substrate 6Y, the refractive index of optical adjustment layer 3 may increase gradually from substrate 6Y lower in refractive index to substrate 6X higher in refractive index. The refractive index may change in the thickness direction. The change of the refractive index may be stepwise or smooth (like gradation). The stepwise change of the refractive index is, for example, obtained when optical adjustment layer 3 is composed of a plurality of layers that differ in refractive index. Optical adjustment layer 3 may have a multilayer structure. The gradational change of the refractive index is, for example, obtained when single-layer optical adjustment layer 3 increases in refractive index in the thickness direction.

In the case where one or both of substrates 6X and 6Y are anisotropic, optical adjustment layer 3 may have the same anisotropy as the anisotropic substrates. This enhances optical transparency, and further improves the optical property. For example, in the case where substrates 6 are made of a resin material (such as PET or PEN), substrates 6 may be anisotropic.

Optical adjustment layer 3 may have ultraviolet absorptivity. In this way, device degradation caused by ultraviolet light can be prevented. Moreover, since ultraviolet light is absorbed, optical switching device 100 has ultraviolet protection effect. This is especially effective in the case where at least one surface of optical switching device 100 is exposed outdoors, as ultraviolet light can be kept from entering indoors. The ultraviolet protection effect is enhanced in the case where the number of optically variable bodies 1 is three or more.

Optical adjustment layer 3 may have low light absorption property, to reduce optical loss.

Optical adjustment layer 3 may be made of a resin composition. The resin may be a thermosetting resin or a light curing resin. The resin composition may include appropriate additives. For example, the inclusion of low refractive particles or high refractive particles enables refractive index adjustment. The inclusion of an ultraviolet absorber provides ultraviolet absorptivity. The material of optical adjustment layer 3 is, for example, cycloolefin polymer (COP). The COP is suitable because of its low light absorption property.

Optical adjustment layer 3 may be a gel material. Optical adjustment layer 3 may be a gel material as long as it is capable of adhesion and optical adjustment. In the case where optical adjustment layer 3 is a gel material, higher shock resistance can be attained. In addition, contraction due to heat stress can be alleviated.

A method of manufacturing optical switching device 100 is described below.

The method of manufacturing optical switching device 100 includes: a step of adhering plurality of optically variable bodies 1 with optical adjustment layer 3 in between; a step of making cut CL in plurality of optically variable bodies 1; and a step of removing side end portion 1x of optically variable bodies 1. The step of making cut CL in plurality of optically variable bodies 1 is a step of making, in the side end portion of plurality of optically variable bodies 1, cut CL from substrate 6 located at one end in the thickness direction to optically variable layer 2 located at the other end in the thickness direction. The step of removing side end portion 1x of optically variable bodies 1 is a step of removing side end portion 1x of optically variable bodies 1 along cut CL to expose electrode 5.

The method of manufacturing optical switching device 100 is described in more detail below, with reference to FIG. 4. Although FIG. 4 illustrates the case where the number of optically variable bodies 1 is two (see FIG. 1), the manufacturing method in the case where the number of optically variable bodies 1 is three (see FIG. 2), four (see FIG. 3), or more can equally be understood from FIG. 4.

As illustrated in A in FIG. 4, plurality of optically variable bodies 1 are individually produced. Each optically variable body 1 can be produced by an appropriate stacking process. Next, as illustrated in B in FIG. 4, plurality of optically variable bodies 1 are adhered by optical adjustment layer 3. The adhesion by optical adjustment layer 3 is, for example, performed by applying the material of optical adjustment layer 3 having adhesiveness to the surface of one optically variable body 1 and placing the other optically variable body 1 onto this surface. Plurality of optically variable bodies 1 are thus attached together. In the case where optical adjustment layer 3 is made of a curing material, optical adjustment layer 3 is formed by curing the material.

Next, as illustrated in C in FIG. 4, cut CL is made in the side end portion of plurality of optically variable bodies 1. For example, cut CI, is made by a cutting tool such as a cutter or laser. Cut CL is formed from substrate 6 located at one end in the thickness direction to optically variable layer 2 located at the other end in the thickness direction. For example, as a cut from the upper side in C in FIG. 4, cut CL is made from substrate 6α to optically variable layer 2α. As a cut from the lower side in C in FIG. 4, cut CL is made from substrate 6β to optically variable layer 2β. Cut CL may be made up to an intermediate point in the thickness direction. Other cut CL may be made as appropriate, to expose plurality of electrodes 5. For example, cut CL from substrate 6α to optically variable layer 2β and cut CL from substrate 6β to optically variable layer 2α are made in C in FIG. 4.

As illustrated in D in FIG. 4, side end portion 1x of one or more optically variable bodies 1 outside cut CL is removed. Since cut CL ends midway in the thickness direction, the portion from substrate 6 to optically variable layer 2 is removed to expose part of electrode 5. Thus, electrode 5 has exposed surface 5s. Exposed surface 5s of electrode 5 is situated in the side end portion of optical switching device 100. Here, adhesion strength AS between optical adjustment layer 3 and substrates 6 is higher than adhesion strength AE between optically variable layer 2 and electrodes 5, as mentioned earlier. Accordingly, when removing side end portion 1x, side end portion 1x to be removed can be integrally removed without separating substrates 6 from each other. This eases manufacturing. It is especially advantageous when the adhesion strength in interfaces FS1 and FS2 is higher than the adhesion strength in interfaces FE1 and FE2 in C in FIG. 4. Interfaces FE1 and FE2 may each be regarded as, in the optically variable unit on the opposite surface of substrate 6 in contact with optical adjustment layer 3, the interface between electrode 5 farther from substrate 6 and optically variable layer 2. Alternatively, interfaces FE1 and FE2 may each be regarded as the interface between electrode 5 in contact with substrate 6 opposite to substrate 6 in contact with optical adjustment layer 3 and optically variable layer 2 in contact with electrode 5. Optical switching device 100 can be manufactured more easily by satisfying the aforementioned adhesion strength relationship between the interfaces.

Lastly, as illustrated in E in FIG. 4, connection wiring 4 is connected to exposed surfaces 5s of electrodes 5. Connection wiring 4 may have an appropriate structure connectable to the power source. For example, connection wiring 4 may be a stack structure of a conductive material, wires, and the like. Connection wiring 4 may cover exposed surface 5s. Optical switching device 100 is manufactured in this way. After this, optical switching device 100 may be attached to a housing. For example, optical switching device 100 may be attached to a frame material that surrounds optical switching device 100. A transparent cover body for covering optical switching device 100 in sheet form may be attached to one or both surfaces of optical switching device 100.

Although the above describes an example where one optically variable layer 2 is located between one pair of substrates 6, two or more optically variable layers 2 may be located between one pair of substrates 6. Moreover, adjacent substrates 6 may be integrated to omit optical adjustment layer 3 in between. When the number of substrates 6 is smaller, the number of interfaces is smaller, which is optically advantageous. Optical switching device 100 includes optical adjustment layer 3 at any position between adjacent substrates 6.

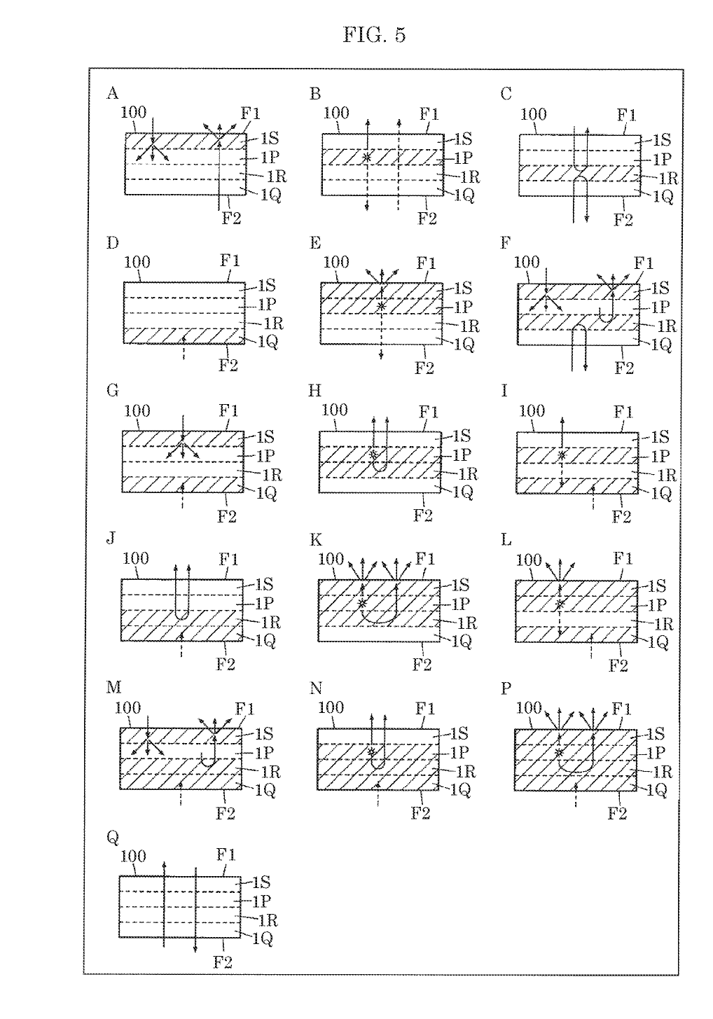

FIG. 5 illustrates examples of the functions of optical switching device 100. The plurality of optically variable units are schematically illustrated in FIG. 5. Each arrow indicates the traveling direction of light. In FIG. 5, light scattering variable unit 1S, sheetlike light emitting unit 1P, light reflection variable unit 1R, and light absorption variable unit 1Q are arranged as the plurality of optically variable units from the first surface F1 side as an example. Optical switching device 100 in FIG. 5 is configured to mainly extract light of sheetlike light emitting unit 1P from first surface F1.

In FIG. 5, each functioning optically variable unit is indicated by diagonal lines. The term “functioning” means the state where light scattering is performed in light scattering variable unit 1S, the state where light is emitted in sheetlike light emitting unit 1P, the state where light reflection is performed in light reflection variable unit 1R, or the state where light absorption is performed in light absorption variable unit 1Q. Each optically variable unit not functioning may be transparent. Although no intermediate state of light scattering, light reflection, or light absorption is illustrated for the same of simplicity, there may be an intermediate state. A to Q in FIG. 5 differ in the states of the functions of the optically variable units, and optical switching device 100 is in a different state in each of A to Q in FIG. 5. Optical switching device 100 may be capable of all of the states in A to Q in FIG. 5, or may be capable of some of the states in A to Q in FIG. 5. Optical switching device 100 can switch its optical state.

As illustrated in FIG. 5, when at least one of the plurality of optically variable units is functioning, light entering optical switching device 100 from outside is unlikely to directly pass through optical switching device 100, and optical switching device 100 may be opaque. For example, in the case where light scattering variable unit 1S performs light scattering as in A in FIG. 5, light is scattered, so that light cannot directly pass through optical switching device 100 between first surface F1 and second surface F2. In the case where light reflection variable unit 1R performs light reflection as in C in FIG. 5, light is reflected, so that light cannot directly pass through optical switching device 100 between first surface F1 and second surface F2. In the case where light absorption variable unit 1Q performs light absorption as in D in FIG. 5, light is absorbed, so that light cannot pass through optical switching device 100 between first surface F1 and second surface F2. Even in the case where sheetlike light emitting unit 1P is functioning as in B in FIG. 5, light emitted from the sheetlike light emitting unit makes the other side less visible, and optical switching device 100 may be opaque. In Q in FIG. 5, on the other hand, no optically variable unit is functioning, and optical switching device 100 is transparent. Thus, optical switching device 100 can change from the transparent state in Q in FIG. 5 to any of the various opaque states in A to P in FIG. 5, and therefore has improved optical property. Particularly when a plurality of optical pattern changes are possible, complex changes are made between opacity and transparency, with it being possible to form a plurality of patterns. Elaborate optical states can be achieved in this way. In FIG. 5, the traveling direction of light is indicated by each arrow. The optical action of optical switching device 100 in each state can be understood from such drawing. The functions of the plurality of optically variable units can also be understood from the foregoing Table 1.

While FIG. 5 illustrates an example of combining four optically variable units of different types, the functions of optical switching device 100 in the case where the number of optically variable units is three or two can equally be understood from this example. Moreover, the functions of optical switching device 100 in the case where the arrangement (order) of the optically variable units is changed can equally be understood based on FIG. 5.

Optical switching device 100 can be used as a window. A window that creates optically different states may be defined as an active window. A window that changes in pattern between opacity and transparency is very useful. The window may be any of an inner window and an outer window. The window may be a transportation window. The transportation window may be a vehicle window of a car, a train, a locomotive, etc., an airplane window, or a ship window. The window variable between opacity and transparency is, for example, suitable for an expensive car. Optical switching device 100 may also be used as a building material. The building material may be a wall material, a partition, a signage, etc. The signage may be an illuminated advertisement. The wall material may be for an outer wall or an inner wall.

In the case where optical switching device 100 includes the sheetlike light emitting unit, optical switching device 100 can be used as a lighting device. Optical switching device 100 can realize a lighting that varies in optical state.

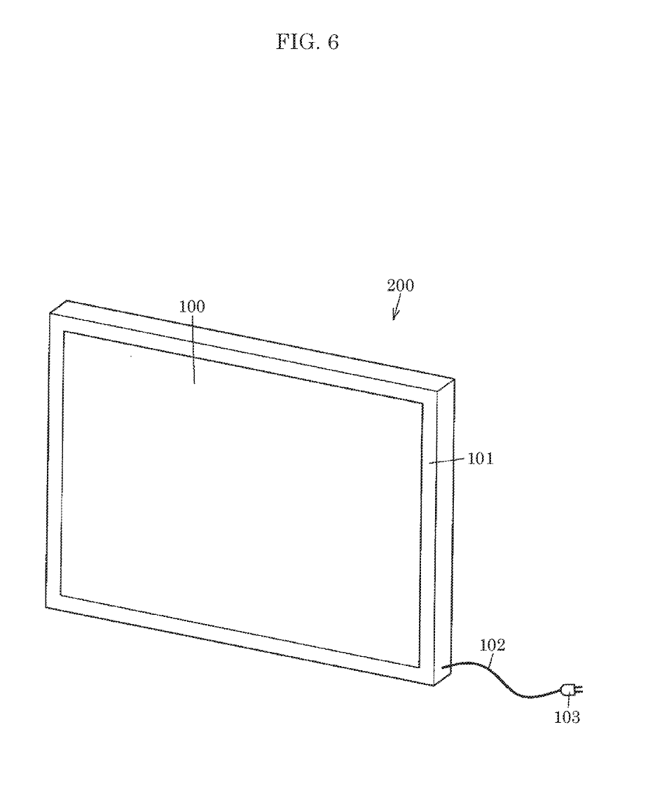

FIG. 6 illustrates an application of optical switching device 100. Building material 200 is illustrated in FIG. 6. Building material 200 in FIG. 6 is a window. Building material 200 includes optical switching device 100. Building material 200 has frame body 101, wiring 102, and plug 103. Building material 200 is an electric building material. Frame body 101 surrounds optical switching device 100. Wiring 102 is electrically connected to optical switching device 100. Plug 103 is connectable to an external power source. When electric power is supplied to optical switching device 100 through plug 103 and wiring 102, the optical state of optical switching device 100 can change. For example, optical switching device 100 changes between a plurality of states such as a transparent state, a translucent (frosted) state, a mirror state, and a light emitting state. Such building material 200 has excellent optical property.

While the optical switching device, the method of manufacturing the same, the building material, and the like have been described above by way of embodiments, the optical switching device and the like according to the present disclosure are not limited to the above embodiments. Other modifications obtained by applying various changes conceivable by a person skilled in the art to the embodiments and any combinations of the structural elements and functions in different embodiments without departing from the scope of the present disclosure are also included in the scope of one or more aspects.

### REFERENCE MARKS IN THE DRAWINGS

1 optically variable body
2 optically variable layer
3 optical adjustment layer
4 connection wiring
5 electrode
6 substrate
CL cut
1x side end portion
5s exposed surface

1-6. (canceled)

7. An optical switching device comprising:
a plurality of optically variable bodies that are sheetlike and are each variable in a degree of an optical state according to electric power; and
an optical adjustment layer located between the plurality of optically variable bodies,
wherein each of the plurality of optically variable bodies includes:
a pair of substrates;
a pair of electrodes located between the pair of substrates; and
an optically variable layer located between the pair of electrodes and variable in the degree of the optical state,
the optical adjustment layer adheres respective substrates of adjacent optical variable bodies of the plurality of optically variable bodies in sheet form in a thickness direction, and adjusts a refractive index between the respective substrates of the adjacent optically variable bodies in a visible light wavelength range,
the pair of electrodes have an exposed surface for supplying the electric power, and
an adhesion strength of the optical adjustment layer to the substrates is higher than an adhesion strength of the optically variable layer to the electrodes.

8. The optical switching device according to claim 7,
wherein the optical adjustment layer has a refractive index between respective refractive indices of the substrates adhered by the optical adjustment layer.

9. The optical switching device according to claim 8,
wherein the refractive index of the optical adjustment layer changes gradually in the thickness direction.

10. The optical switching device according to claim 7,
wherein the optical adjustment layer has ultraviolet absorptivity.

11. A building material comprising:
the optical switching device according to claim 7; and
wiring.

12. A method of manufacturing the optical switching device according to claim 7, the method comprising:
adhering the plurality of optically variable bodies with the optical adjustment layer in between;
making, in a side end portion of the plurality of optically variable bodies, a cut from a substrate located at one end in the thickness direction to an optically variable layer located at an other end in the thickness direction; and
removing the side end portion of the plurality of optically variable bodies along the cut to expose an electrode.
